(19) United States
(12) Patent Application Publication
(10) Pub. No.: US 2026/0164947 A1
(43) Pub. Date: Jun. 11, 2026

(54) DISPLAY DEVICE, METHOD OF MANUFACTURING THE SAME AND ELECTRONIC DEVICE INCLUDING THE SAME

(71) Applicant: Samsung Display Co., Ltd., Yongin-Si (KR)

(72) Inventor: Hyun Eok SHIN, Yongin-si (KR)

(21) Appl. No.: 19/281,763

(22) Filed: Jul. 28, 2025

(30) Foreign Application Priority Data
Dec. 11, 2024 (KR) 10-2024-0183848

(51) Int. Cl. H10K 59/123; H10K 59/12; H10K 59/124

(52) U.S. Cl. CPC H10K 59/123; H10K 59/1201; H10K 59/124

(57) ABSTRACT

A display device includes a base substrate, an active layer disposed on the base substrate and including a contact region and a channel region, an intermediate conductive layer disposed on a top surface of the contact region of the active layer, an etch-stop pattern disposed on a peripheral portion of a top surface of the intermediate conductive layer, a gate electrode overlapping the channel region of the active layer, a gate insulation layer disposed between the active layer and the gate electrode, an insulating interlayer covering the gate electrode on the gate insulation layer, a contact electrode extending through the insulating interlayer and the gate insulation layer to be disposed on the top surface of the intermediate conductive layer, and a display element electrically connected to the contact electrode.

### CROSS-REFERENCE TO RELATED APPLICATION AND CLAIM OF PRIORITY

This application claims priority to Korean Patent Application No. 10-2024-0183848 filed on Dec. 11, 2024 in the Korean Intellectual Property Office (KIPO), the entire disclosure of which is incorporated by reference herein.

### TECHNICAL FIELD

Embodiments of the present disclosure relate to a display device, a method of manufacturing the same and electronic device including the same. More particularly, embodiments of the present disclosure relate to a display device including a transistor and electrodes, a method of manufacturing the display device, and electronic device including the display device.

### BACKGROUND

In a display device such as an organic light emitting diode (OLED) display device and a liquid crystal display (LCD) device, a display substrate including, e.g., a thin film transistor (TFT) and various wirings may be provided, and a display structure including electrodes and emission layers may be formed on the display substrate.

For example, electrodes connecting the TFT and the display structure may be disposed. Recently, various constructions of the TFT and the electrodes for stable implementation of a high-resolution display device have been researched

### SUMMARY

According to an aspect of the present disclosure, there is provided a display device having improved electrical properties and structural reliability.

According to an aspect of the present disclosure, there is provided a method of manufacturing a display device having improved electrical properties and structural reliability.

According to an aspect of the present disclosure, there is provided an electronic device having improved electrical properties and structural reliability.

A display device may include a base substrate, an active layer disposed on the base substrate and including a contact region and a channel region, an intermediate conductive layer disposed on a top surface of the contact region of the active layer, an etch-stop pattern disposed on a peripheral portion of a top surface of the intermediate conductive layer, a gate electrode overlapping the channel region of the active layer, a gate insulation layer disposed between the active layer and the gate electrode, an insulating interlayer covering the gate electrode on the gate insulation layer, a contact electrode extending through the insulating interlayer and the gate insulation layer to be disposed on the top surface of the intermediate conductive layer, and a display element electrically connected to the contact electrode.

In some embodiments, the intermediate conductive layer may include a metal layer, and the etch-stop pattern may include a transparent metal oxide.

In some embodiments, the intermediate conductive layer may include titanium (Ti).

In some embodiments, the etch-stop pattern may surround a bottom portion of the contact electrode.

In some embodiments, the etch-stop pattern may include an under-cut portion.

In some embodiments, the contact electrode may include a vertical extension portion, and a horizontal extension portion having a width greater than a width of the vertical extension portion and contacting the under-cut portion of the etch-stop pattern.

In some embodiments, the contact electrode may have a single-layered metal pillar shape.

In some embodiments, the display device may further include a connection wiring disposed on the insulating interlayer to connect the display element and the contact electrode with each other. The connection wiring may have a multi-layered structure.

In some embodiments, the connection wiring may include a first metal layer, a second metal layer and a third metal layer sequentially stacked from a top surface of the contact electrode.

In some embodiments, the first metal layer and the third metal layer may include a metal the same as a metal of the intermediate conductive layer, and the second metal layer may include a metal different from the metal of the intermediate conductive layer.

In some embodiments, the first metal layer and the third metal layer may include titanium (Ti), and the second metal layer may include aluminum (Al).

An electronic device may include the above-described display device, a memory, and one or more processors executing data included in the memory to control an operation of the display device.

In some embodiments, the electronic device may include a virtual reality or augmented reality display, a mobile phone, a tablet, a PC monitor, a digital camera, a camcorder, a portable game console, a vehicle display, a head-up display, a wearable display, a flexible display, a rollable display, or a foldable display.

A display device may include a base substrate, an active layer disposed on the base substrate and including a contact region and a channel region, a gate electrode overlapping the channel region of the active layer, a gate insulation layer disposed between the active layer and the gate electrode, an insulating interlayer covering the gate electrode on the gate insulation layer, a contact hole extending through the insulating interlayer and the gate insulation layer and overlapping the contact region, a contact electrode partially filling the contact hole on the contact region, a connection wiring filling a remaining portion of the contact hole to be connected to the contact electrode and having a multi-layered structure, and a display element electrically connected to the connection wiring.

In some embodiments, the display device may further include an intermediate conductive layer disposed between the contact electrode and the contact region, and an etch-stop pattern disposed on a peripheral portion of a top surface of the intermediate conductive layer to surround a bottom portion of the contact electrode.

In some embodiments, the intermediate conductive layer may include a metal layer, and the contact electrode may have a single-layered pillar shape including a metal different from a metal of the intermediate conductive layer.

In some embodiments, the etch-stop pattern may include a transparent metal oxide.

In some embodiments, the connecting wiring may include a first metal layer, a second metal layer and a third metal layer sequentially stacked from a top surface of the contact electrode.

In a method of manufacturing a display device, an active layer may be formed on a base substrate. An intermediate conductive layer and an etch-stop layer may be sequentially formed on a side portion of the active layer. A gate insulation layer covering the active layer, the intermediate conductive layer and the etch-stop layer may be formed. A gate electrode overlapping the active layer may be formed on the gate insulation layer. An insulating interlayer covering the gate electrode may be formed on the gate insulation layer. The insulating interlayer and the gate insulating layer may be etched by a first etching process to form a contact hole exposing a top surface of the etch-stop layer. The etch-stop layer may be partially etched by a second etching process to extend the contact hole so that a top surface of the intermediate conductive layer may be exposed. A contact electrode filling the contact hole may be formed by a plating process from the top surface of the intermediate conductive layer exposed by the contact hole. A light-emitting element electrically connected to the contact electrode may be formed.

In some embodiments, the first etching process may include a dry etching and the second etching process may include a wet etching.

In a display device according to embodiments of the present inventive concepts, a contact electrode connected to a contact region of an active layer may be formed by a plating process using an intermediate conductive layer and an etch-stop layer. Accordingly, a stable contact electrode may be formed while suppressing disconnection and void generation in a contact hole having a high aspect ratio included in a high-resolution display device.

In some embodiments, a contact wiring having a multi-layered structure may be formed on the contact electrode by filling a remaining portion of the contact hole. Accordingly, a step coverage in a deposition process may be improved, and disconnection and void generation in the contact wiring may also be suppressed.

### BRIEF DESCRIPTION OF THE DRAWINGS

FIG. 1 is a schematic cross-sectional view of a display panel or a display device including a thin film transistor according to embodiments.

FIG. 2 is a schematic cross-sectional view of a display panel or a display device including a thin film transistor according to embodiments.

FIGS. 3 and 4 are schematic cross-sectional views illustrating light-emitting elements according to embodiments.

FIG. 5 is a partially enlarged cross-sectional view illustrating a contact portion according to embodiments.

FIG. 6 is a partially enlarged cross-sectional view illustrating a contact portion according to a comparative example.

FIG. 7 is a schematic cross-sectional view illustrating a display panel or a display device according to embodiments.

FIGS. 8, 9, 10, 11, 12, 13, 14, 15, 16, 17, 18, 19, and 20 are schematic cross-sectional views describing a method of manufacturing a display panel or a display device according to embodiments.

FIG. 21 is an exploded perspective view of a display device according to embodiments.

FIG. 22 is a schematic plan view illustrating an arrangement of pixels of a display device according to embodiments.

FIG. 23 is a pixel equivalent circuit diagram of a display device according to embodiments.

FIG. 24 is a block diagram of an electronic device in accordance with an embodiment.

FIG. 25 is a schematic diagram of electronic devices in accordance with various embodiments.

### DETAILED DESCRIPTION OF THE EMBODIMENTS

Hereinafter, embodiments of the inventive concept will be described in more detail with reference to the attached drawings. The same reference numerals can be used for indicating the same elements in the drawings, and repeated descriptions of the same elements can be omitted. Embodiments disclosed in the attached drawings are exemplary, and is to be understood to include all modifications, equivalents and substitutes included in the spirit and technical scope of the inventive concept.

The terms “on”, “connected”, “coupled,” etc., used herein refers to a direct placement/connection/combination, and also refers to a case where another element is interposed two different elements.

The terms such as “first”, “second”, “below”, “above,” etc., are used in a relative sense to distinguish different elements or positions, and do not specify an absolute position or an absolute order.

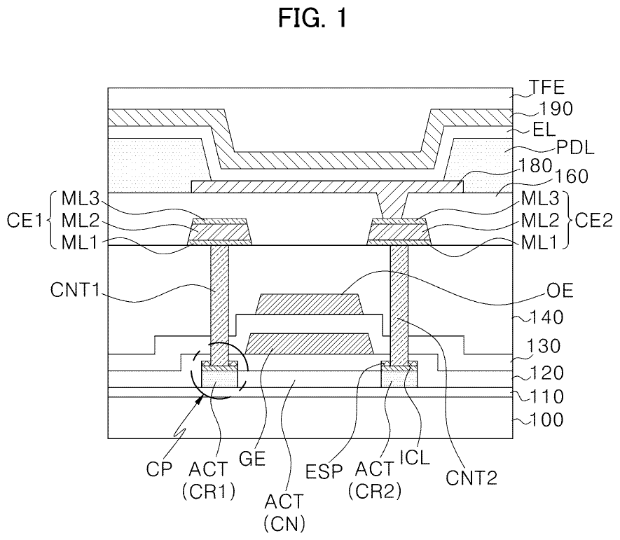

FIG. 1 is a schematic cross-sectional view of a display panel or a display device including a thin film transistor according to embodiments.

Referring to FIG. 1, a transistor of a thin film transistor (TFT) type including an active layer ACT may be disposed on a base substrate 100. According to embodiments, a plurality of the transistors may be arranged on the base substrate 100 to provide a display panel in the form of a TFT-array substrate and a display device including the display panel.

The display panel or the display device may include a light-emitting element connected to the transistor, and the light-emitting element may be connected to the transistor through a contact electrode and a wiring.

The base substrate 100 may serve as a back-plane substrate of the display device or the display panel. A glass substrate or a plastic substrate may be used as the base substrate 100.

In some embodiments, the base substrate 100 may include a polymer material having transparency and flexibility. For example, the base substrate 100 may include a polymer material such as polyimide, polysiloxane, an epoxy resin, an acrylic resin, polyester, or the like. In an embodiment, the base substrate 100 may include polyimide.

In some embodiments, a glass substrate may be used as the base substrate 100.

A barrier layer 110 may be formed on a top surface of the base substrate 100. Moisture penetrating through the base substrate 100 may be blocked by the barrier layer 110, and diffusion of impurities between the base substrate 100 and structures formed on the base substrate 100 may be blocked. The barrier layer 110 may cover the entire top surface of the base substrate 100.

The barrier layer 110 may include, e.g., an inorganic insulating material such as silicon oxide, silicon nitride, silicon oxynitride, or the like. These may be used alone or in a combination thereof. In some embodiments, the barrier layer 110 may have a stacked structure including a silicon oxide layer and a silicon nitride layer. In some embodiments, the barrier layer 110 may include an organic layer, and may have a multi-layered structure of the organic layer and an inorganic layer.

The transistor may be disposed on the barrier layer 110. The transistor may include the active layer ACT and a gate electrode GE. A first gate insulation layer 120 may be disposed between the active layer ACT and the gate electrode GE.

According to embodiments, the active layer ACT may include a silicon-based semiconductor (e.g., polysilicon or amorphous silicon). In an embodiment, the active layer ACT may include an oxide semiconductor such as indium gallium-zinc oxide (IGZO), zinc-tin oxide (ZTO), or ITZO.

The active layer ACT may include a channel region CN and contact regions CR1 and CR2. The contact regions CR1 and CR2 may have an increased conductivity than that of the channel region CN. For example, the contact regions CR1 and CR2 may include the silicon-based semiconductor doped with a p-type or an n-type impurity. In some embodiments, the contact regions CR1 and CR2 may include a p-type impurity.

The contact regions CR1 and CR2 may include a first contact region CR1 and a second contact region CR2. A region between the first contact region CR1 and the second contact region CR2 may be defined as the channel region CN. For example, the first contact region CR1 and the second contact region CR2 may be formed at one side or end portion or the other side or end portion of the active layer ACT, respectively.

The contact regions CR1 and CR2 may be provided as source/drain regions. For example, the first contact region CR1 and the second contact region CR2 may be provided as a source region and a drain region, respectively.

An intermediate conductive layer ICL may be formed on the contact regions CR1 and CR2, and an etch-stop pattern ESP may be disposed on the intermediate conductive layer ICL. According to embodiments, the intermediate conductive layer ICL and the etch-stop pattern ESP may be sequentially disposed from a top surface of each of the contact regions CR1 and CR2. The intermediate conductive layer ICL may be in contact with the top surfaces of the contact regions CR1 and CR2, and the etch-stop pattern ESP may be in contact with a top surface of the intermediate conductive layer ICL.

The intermediate conductive layer ICL may include a metal relatively stable to oxidation and corrosion. For example, the intermediate conductive layer ICL may include Ti, Ni, Cr, Mo, Pt, Ta, Nd, Sn, Sc, or the like. In some embodiments, the intermediate conductive layer ICL may include titanium (Ti).

The etch-stop pattern ESP may include a transparent metal oxide. For example, the etch-stop pattern ESP may include a transparent conductive oxide or an oxide semiconductor such as indium tin oxide (ITO), indium zinc oxide (IZO), zinc oxide (ZnO), indium tin zinc oxide (ITZO), indium gallium zinc oxide (IGZO), etc.

The first gate insulation layer 120 may be formed on the barrier layer 110 to cover the active layer ACT. The first gate insulation layer 120 may also cover the etch-stop pattern ESP and the intermediate conductive layer ICL. The gate electrode GE may be disposed on the first gate insulation layer 120. The gate electrode GE may substantially overlap the channel region CN in a thickness direction with the first gate insulation layer 120 interposed therebetween.

As illustrated in FIG. 1, the transistor may have a top-gate structure in which the gate electrode GE is disposed on the active layer ACT.

In an embodiment, the transistor may have a bottom-gate structure in which the gate electrode GE is disposed under the active layer ACT. In this case, the gate electrode GE may be disposed on the barrier layer 110, and the first gate insulation layer 120 may cover the gate electrode GE. The active layer ACT may be disposed on the first gate insulation layer 120 such that the channel region CN may overlap the gate electrode GE with the first gate insulation layer 120 interposed therebetween.

Hereinafter, elements/structures of the transistor and the display device will be described based on embodiments including the top-gate structure.

A second gate insulation layer 130 may be formed on the first gate insulation layer 120 to cover the gate electrode GE. An overlapping electrode OE may be disposed on the second gate insulation layer 130.

The overlapping electrode OE may substantially overlap the gate electrode GE in the thickness direction with the second gate insulating layer 130 interposed therebetween. In some embodiments, the overlapping electrode OE may serve as an upper gate electrode. In some embodiments, a storage capacitor may be formed by the overlapping electrode OE, the second gate insulation layer 130 and the gate electrode GE.

The first and second gate insulation layers 120 and 130 may include an inorganic insulating material such as silicon oxide, silicon nitride, silicon oxynitride, aluminum oxide, titanium oxide, tantalum oxide, hafnium oxide, or the like.

The gate electrode GE and the overlapping electrode OE may include a metal such as tungsten (W), molybdenum (Mo), aluminum (Al), copper (Cu), titanium (Ti), chromium (Cr), nickel (Ni), silver (Ag), or the like, or an alloy including at least one therefrom.

An insulating interlayer 140 covering the transistor and the overlapping electrode OE may be formed on the second gate insulation layer 130. The insulating interlayer 140 may include an inorganic insulating material such as silicon oxide, silicon nitride, silicon oxynitride, aluminum oxide, titanium oxide, tantalum oxide, hafnium oxide, or the like. The insulating interlayer 140 may have a single-layered structure or a multi-layered structure including different materials (e.g., silicon oxide and silicon nitride).

Contact electrodes CNT1 and CNT2 may be electrically connected to the contact regions CR1 and CR2. The contact electrodes CNT1 and CNT2 may include a first contact electrode CNT1 and a second contact electrode CNT2 connected to or disposed on the first contact region CR1 and the second contact region CR2, respectively. In some embodiments, the first contact electrode CNT1 may serve as a source contact or a source electrode, and the second contact electrode CNT2 may serve as a drain contact or a drain electrode.

The contact electrodes CNT1 and CNT2 may penetrate, e.g., extend through, the insulating interlayer 140 and the gate insulation layers 120 and 130 to be landed on the intermediate conductive layer ICL. According to embodiments of the present disclosure, bottom surfaces of the contact electrodes CNT1 and CNT2 may be in contact with the top surface of the intermediate conductive layer ICL.

A side surface of a bottom portion which is in contact with or adjacent to the intermediate conductive layer ICL of the contact electrodes CNT1 and CNT2 may be in contact with the etch-stop pattern ESP. According to embodiments, the bottom portion of the contact electrodes CNT1 and CNT2 may be substantially surrounded by the etch-stop pattern ESP.

The contact electrodes CNT1 and CNT2 may include a metal. The contact electrodes CNT1 and CNT2 may include a plating metal formed by using the intermediate conductive layer ICL as a seed layer. The contact electrodes CNT1 and CNT2 may include a metal different from that of the intermediate conductive layer ICL. According to embodiments, the contact electrodes CNT1 and CNT2 may include copper. For example, the contact electrodes CNT1 and CNT2 may have a Cu-pillar shape.

A contact portion CP may be defined by the intermediate conductive layer ICL, the etch-stop pattern ESP, and the bottom portion of the contact electrodes CNT1 and CNT2 stacked on the contact regions CR1 and CR2.

Connection wirings CE1 and CE2 electrically connected to the contact electrodes CNT1 and CNT2 may be disposed on the insulating interlayer 140. The connection wirings CE1 and CE2 may include connection electrodes disposed on the contact electrodes CNT1 and CNT2.

The connection wirings CE1 and CE2 may include a first connection wiring CE1 connected to or in contact with the first contact electrode CNT1, and a second connection wiring CE2 connected to or in contact with the second contact electrode CNT2. For example, the first connection wiring CE1 may serve as a source wiring or a source electrode. The second connection wiring CE2 may serve as a drain wiring or a drain electrode.

According to embodiments, the connection wiring CE1 and CE2 may have a multi-layered structure. For example, the connection wiring CE1 and CE2 may include a first metal layer ML1, a second metal layer ML2, and a third metal layer ML3 sequentially stacked from the top surface of the contact electrodes CNT1 and CNT2.

According to embodiments, the first metal layer ML1 and the third metal layer ML3 may include a metal that may be relatively more stable to oxidation or corrosion than that of the second metal layer ML2. In some embodiments, the first metal layer ML1 and the third metal layer ML3 may include substantially the same metal as that of the intermediate conductive layer ICL. The second metal layer ML2 may include a metal having a relatively lower resistance than that of the first metal layer ML1 and the third metal layer ML3.

In an embodiment, the first metal layer ML1, the second metal layer ML2, and the third metal layer ML3 may be a Ti layer, an Al layer, and a Ti layer, respectively.

A planarization layer 160 covering the connection wirings CE1 and CE2 may be formed on the insulating interlayer 140. The planarization layer 160 may include an organic material such as polyimide, an epoxy resin, an acrylic resin, polyester, a siloxane resin, a benzocyclobutene (BCB), or the like.

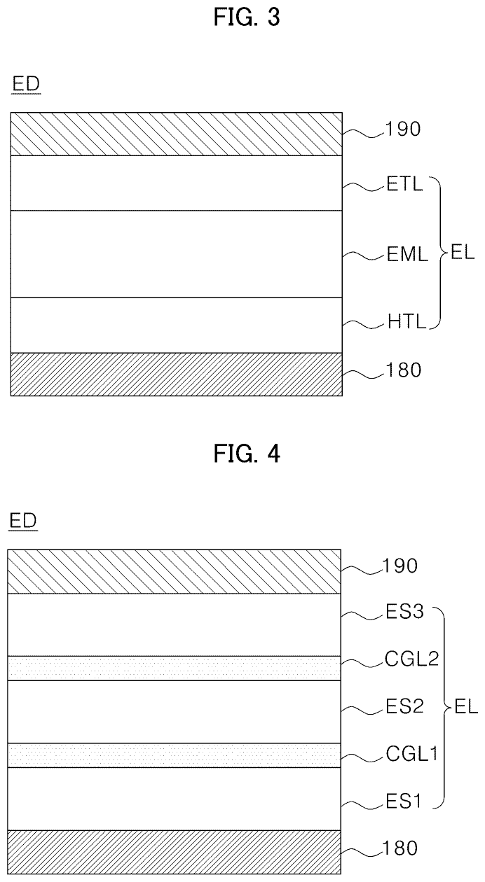

A display element electrically connected to the transistor through connection wires CE1 and CE2 and contact electrodes CNT1 and CNT2 may be disposed on the planarization layer 160. The display element may include a light-emitting element ED (see FIG. 3 or 4).

The light-emitting element ED may include a first electrode 180, a light-emitting portion EL, and a second electrode 190.

The first electrode 180 may be disposed on the planarization layer 160 and may include a via electrode penetrating, e.g., extending through, the planarization layer 160 to be in contact with or connected to the second connection wiring CE2.

The first electrode 180 may serve as a pixel electrode or an anode, and may include a high work function conductive material that may promote hole injection. The first electrode 180 may be formed as a transmissive electrode. The first electrode 180 may include a transparent conductive oxide such as indium tin oxide (ITO), indium zinc oxide (IZO), zinc oxide (ZnO), indium tin oxide (ITZO), or the like.

The first electrode 180 may be provided as a translucent electrode or a reflective electrode. The first electrode 180 may include a metal selected from Ag, Mg, Cu, Al, Pt, Pd, Au, Ni, Nd, Ir, Cr, Li, Ca, LiF, Mo, Ti, W, In, Sn and Zn, or an alloy containing at least one therefrom.

The first electrode 180 may have a single-layered structure or a multi-layered structure. For example, the first electrode 180 may have a three-layer structure of ITO/Ag/ITO.

A pixel defining layer PDL may be formed on the planarization layer 160 to at least partially expose a top surface of the first electrode 180. The pixel defining layer PDL may cover a peripheral portion of the first electrode 180.

A light-emitting region may be defined by a sidewall of the pixel defining layer PDL. For example, a green light-emitting region, a blue light-emitting region, and a light-emitting region area may be separated and defined by the pixel defining layer PDL.

The pixel defining layer PDL may include, e.g., an organic material such as a polysiloxane resin, a polyimide resin, an acrylic resin, or the like. The pixel defining layer PDL may include a colorant material such as a black pigment/dye dispersed in a resin material.

The light-emitting portion EL may be disposed on the first electrode 180 and the pixel defining layer PDL. The light-emitting portion EL may include an organic light-emitting layer that may be independently patterned for each of a red pixel, a green pixel, and a blue pixel to generate different colored lights for each of the pixels.

In an embodiment, the light-emitting portion EL may continuously and commonly extend throughout a plurality of pixels. In this case, the light-emitting portion EL may include a white light-emitting layer or a blue light-emitting layer. In an embodiment, the light-emitting portion EL may include emission layers corresponding to a plurality of different colored lights, and may include a stack having a tandem structure.

The light-emitting element ED including the light-emitting portion EL will be described in more detail with reference to FIGS. 3 and 4.

The second electrode 190 may be disposed on the light-emitting portion EL. The second electrode 190 may be a common electrode continuously and commonly provided in a plurality of the light-emitting regions or the pixels.

The second electrode 190 may serve as an electron injection electrode or a cathode. The second electrode 190 may include a metal, an alloy, an electrically conductive compound, or the like, having a low work function.

For example, the second electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or the like. These may be used alone or in a combination thereof.

The second electrode 190 may be formed as a transmissive electrode, a translucent electrode or a reflective electrode. The second electrode 190 may have a single-layered structure or a multi-layered structure.

The light-emitting element ED may be defined by the first electrode 180, the light emitting portion EL, and the second electrode 190 as described above. The light-emitting element ED may be provided as an organic light-emitting diode (OLED) element.

An encapsulation layer TFE may be formed on the second electrode 190. The encapsulation layer TFE may be disposed on the pixel defining layer PDL and the light-emitting elements to protect the light-emitting elements from moisture or oxygen.

The encapsulation layer TFE may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE), or any combination thereof; or a combination of the inorganic and organic layers.

The encapsulation layer TFE may be formed in a single-layered structure or a multi-layered structure. In some embodiments, the encapsulation layer TFE may have a sequential stacked structure of a first inorganic layer, an organic layer, and a second inorganic layer.

In some embodiments, a color control layer overlapping the light-emitting portion EL may be disposed on the encapsulation layer TFE. The color control layer may include a color conversion layer including quantum dots and/or a color filter.

According to the above-described embodiments, the contact electrodes CNT1 and CNT2 connected to the contact regions CR1 and CR2 through the intermediate conductive layer ICL may be formed in a plated pillar shape. Thus, as described later, a conductor or an electrode may be formed while suppressing a defect such as a disconnection or a void in a contact hole having a high aspect ratio used in a high-resolution display device.

Additionally, the connection wirings CE1 and CE2 of the desired multi-layered structure may be easily formed using the contact electrodes CNT1 and CNT2.

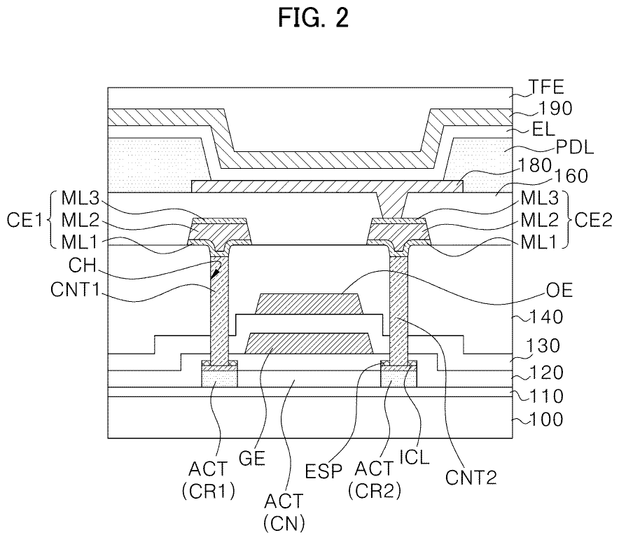

FIG. 2 is a schematic cross-sectional view of a display panel or a display device including a thin film transistor according to embodiments. Detailed descriptions on elements and structures substantially the same as or similar to those described with reference to FIG. 1 are omitted.

Referring to FIG. 2, the contact electrodes CNT1 and CNT2 may partially fill a contact hole CH. The connection wirings CE1 and CE2 may be disposed on a top surface of the insulating interlayer 140 to fill a remaining portion of the contact hole CH.

The contact hole CH may penetrate, e.g., extend through, the insulating interlayer 140 and the gate insulation layer 120 and 130 to expose a top surface of the intermediate conductive layer ICL. As described above, the contact electrodes CNT1 and CNT2 may be formed to partially fill the contact hole CH by a plating process.

As described above, e.g., the first metal layer ML1 including titanium (Ti) may be formed on the top surface of the insulating interlayer 140, a sidewall of the remaining portion of the contact hole CH, and a top surface of the contact electrode CNT1 and CNT2. The second metal layer ML2 and the third metal layer ML3 may be sequentially disposed on the first metal layer ML1.

The contact electrode CNT1 and CNT2 may partially fill the contact hole CH, so that the first metal layer ML1 may contact the sidewall of the contact hole CH. Thus, the first metal layer ML1 may be more stably attached to the contact electrode CNT1 and CNT2.

According to above-described embodiments, the first metal layer ML1 and the intermediate conductive layer ICL may function as a blocking layer preventing diffusion of copper included in the contact electrode CNT1 and CNT2. Further, the first metal layer ML1 and the intermediate conductive layer ICL may function as an intermediate layer providing adhesion and anti-corrosion properties of the second metal layer ML2 and the contact electrode CNT1 and CNT2, respectively.

FIGS. 3 and 4 are schematic cross-sectional views illustrating light-emitting elements ED according to embodiments.

Referring to FIG. 3, as described above, the light-emitting element ED may include the first electrode 180 and the second electrode 190, and the light-emitting portion EL disposed between the first electrode 180 and the second electrode 190.

The light-emitting portion EL may include a hole transport layer HTL, an emission layer EML, and an electron transport layer ETL. According to embodiments, the hole transport layer HTL, the emission layer EML, the electron transport layer ETL, and the second electrode 190 may be sequentially stacked from a top surface of the first electrode 180.

The emission layer EML may include an organic light-emitting material having red, green, or blue emission properties. For example, the emission layer EML may include a fluorescent host and/or a host for a phosphorescent device, and may further include a fluorescent dopant, a phosphorescent dopant, and/or a thermally activated delayed fluorescence (TADF) dopant.

For example, hole transport layer HTL may include a hole transporting material such as m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalene-l-yl)-N,N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), PEDOT/PSS (poly(3,4-ethylenedioxythiophene)/poly(4-styrenesulfonate)), or the like.

For example, electron transport layer ETL may include an electron transporting material such as an anthracene-based compound, Alq₃ (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), or the like.

In some embodiments, a hole injection layer may be further disposed between the first electrode 180 and the hole transport layer HTL. An electron injection layer may be further disposed between the second electrode 190 and the electron transport layer ETL.

Referring to FIG. 4, the light-emitting portion EL may include a plurality of light-emitting structures ES1, ES2 and ES3. Each of the light-emitting structures ES1, ES2, and ES3 may include a hole transport layer, an emission layer and an electron transport layer. According to embodiments, the light-emitting element ED of FIG. 4 may be a light-emitting element having a tandem structure that generates a white light or a blue light.

Charge generation layers CGL1 and CGL2 may be disposed between neighboring light-emitting structures ES1, ES2 and ES3. The charge generation layers CGL1 and CGL2 may include a p-type charge generation layer and/or an n-type charge generation layer. The charge generation layers CGL1 and CGL2 may include a first charge generation layer CGL1 between the first light-emitting structure ES1 and the second light-emitting structure ES2, and a second charge generation layer CGL2 between the second light-emitting structure ES2 and the third light-emitting structure ES3.

According to embodiments, the first light-emitting structure ES1, the first charge generation layer CGL1, the second light-emitting structure ES2, the second charge generation layer CGL2, the third light-emitting structure ES3 and the second electrode 190 may be sequentially stacked from the top surface of the first electrode 180.

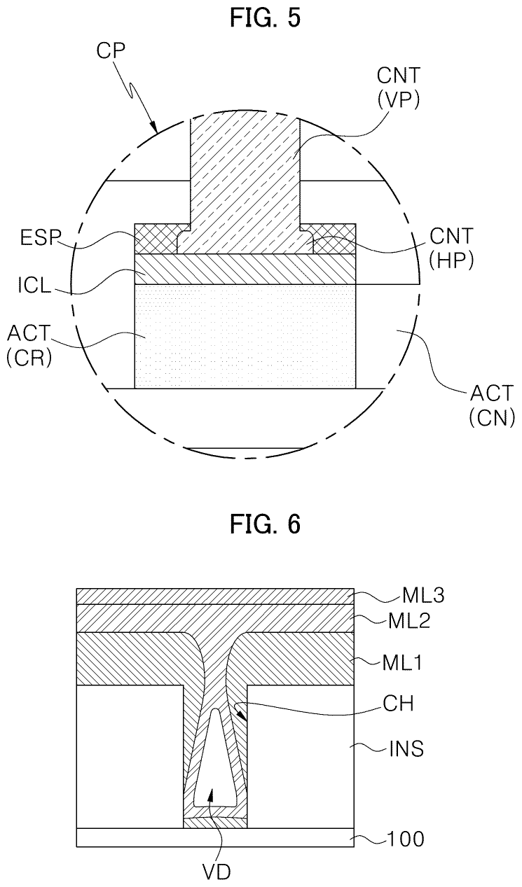

FIG. 5 is a partially enlarged cross-sectional view illustrating a contact portion CP according to embodiments.

Referring to FIG. 5, as described above, the contact portion CP may include the contact region CR formed at a side portion or an end portion of the active layer ACT, the intermediate conductive layer ICL formed on a top surface of the contact region CR, the contact electrode CNT disposed on the top surface of the intermediate conductive layer ICL, and the etch-stop pattern ESP that may be disposed on the top surface of the intermediate conductive layer ICL and may surround a side surface of the bottom portion of the contact electrode CNT.

In some embodiments, a bottom portion of the contact electrode CNT may have an expanded width. For example, the contact electrode CNT may include a vertical extension portion VP and a horizontal extension portion HP. The horizontal extension portion HP may be formed at the bottom portion of the contact electrode CNT and may have a width greater than that of the vertical extension portion VP.

According to embodiments, the etch-stop pattern ESP may have an under-cut shape. An under-cut portion of the etch-stop pattern ESP may substantially surround the horizontal extension portion HP of the contact electrode CNT. Accordingly, a contact area between the contact electrode CNT and the etch-stop pattern ESP may be increased, and stability of the contact electrode CNT may be enhanced. Accordingly, separation, detachment, etc., of the contact electrode CNT from the contact portion CP may be prevented.

FIG. 6 is a partially enlarged cross-sectional view illustrating a contact portion according to a comparative example. For convenience of descriptions, illustration of the active layer (or the contact region) is omitted in FIG. 6.

Referring to FIG. 6, a contact hole CH exposing the active layer (or the contact region) may be formed in an insulation layer INS. To form a contact electrode which is in contact with or connected to the contact region, the first metal layer ML1, the second metal layer ML2 and the third metal layer ML3 sufficiently filling the contact hole CH may be sequentially formed on the top surface of the insulation layer INS. Each of the first metal layer ML1, the second metal layer ML2, and the third metal layer ML3 may be formed by a deposition process such as a sputtering process.

As an aspect ratio of the contact hole CH increases, a width of the contact hole CH may be relatively decreased. Accordingly, an overhang of the first metal layer ML1 may occur at an upper portion of the contact hole CH due to limitation of step coverage of the deposition process. Accordingly, the second metal layer ML2 may not sufficiently fill the contact hole CH, thereby causing a void VD in the contact electrode.

Due to the void VD, response properties of the display device may be deteriorated due to an increase in resistance of the contact electrode. Further, mechanical defects such as collapse and disconnection of the contact electrode may occur.

However, according to the above-described embodiments, the contact electrode CNT may be formed in, e.g., a copper-pillar shape through a plating process using an intermediate conductive layer ICL. Accordingly, the contact electrode CNT having a stable high aspect ratio may be obtained while avoiding the step coverage limit of the deposition process. Additionally, the connection wirings CE1 and CE2 may be formed on the contact electrode CNT by the deposition process, so that the connection electrode shape having a desired multi-layered structure may be easily implemented.

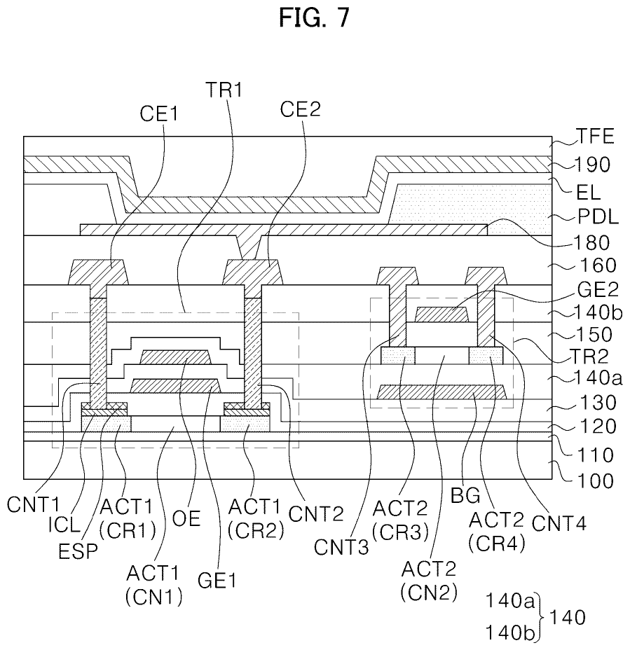

FIG. 7 is a schematic cross-sectional view illustrating a display panel or a display device according to embodiments. Detailed descriptions on elements and structures described with reference to FIGS. 1 to 6 are omitted.

Referring to FIG. 7, the display device may include a first transistor element TR1 and a second transistor element TR2. According to embodiments, the first transistor element TR1 may include a transistor including the contact portion CP described with reference to FIGS. 1, 2 and 3. In some embodiments, the first transistor element TR1 may serve as a pixel driving transistor.

As described above, the first transistor device TR1 may include a first channel region CN1, and the first and second contact regions CR1 and CR2. The intermediate conductive layer ICL may be formed on each of the first and second contact regions CR1 and CR2, and the contact electrodes CNT1 and CNT2 may be disposed or in contact with a top surface of the intermediate conductive layer ICL. The etch-stop pattern ESP may be disposed on a peripheral portion of the top surface of the intermediate conductive layer ICL, and may be in contact with side surfaces of the contact electrodes CNT1 and CNT2.

The second transistor element TR2 may include a second active layer ACT2, a second gate electrode GE2, and third and fourth contact electrodes CNT3 and CNT4. The second transistor element TR2 may further include a rear metal layer BG. In some embodiments, the second transistor element TR2 may serve as a switching transistor.

The insulating interlayer 140 may include a first insulating interlayer 140a and a second insulating interlayer 140b. The first insulating interlayer 140a may be formed on the second gate insulation layer 130 to cover the overlapping electrode OE of the first transistor element TR1 and the rear metal layer BG of the second transistor element TR2.

The rear metal layer BG may overlap the second active layer ACT2 in the thickness direction. The rear metal layer BG may serve as a blocking layer with respect to external light for the second transistor element TR2. The rear metal layer BG may serve a bias electrode or a back-gate electrode. In an embodiment, the rear metal layer BG may be an island-shaped floating electrode separated from another wiring or electrode.

The second active layer ACT2 of the second transistor element TR2 may be disposed at an upper level with respect to a top surface of the base substrate 100 than that of the first active layer ACT1 of the first transistor element TR1. According to embodiments, the second active layer ACT2 may be disposed on a top surface of the first insulating interlayer 140a.

In some embodiments, the second active layer ACT2 may include the above-described oxide semiconductor, and the first active layer ACT1 may include the above-described silicon-based semiconductor material.

A third contact region CR3 and a fourth contact region CR4 may be formed at one side portion and the other side portion of the second active layer ACT2, respectively. For example, the third contact region CR3 and the fourth contact region CR4 may be provided as a source region and a drain region of the second active layer ACT2, respectively.

A portion of the second active layer ACT2 between the third contact region CR3 and the fourth contact region CR4 may be defined as a second channel region CN2. The third contact region CR3 and the fourth contact region CR4 may be formed as, e.g., an n-doped regions.

A third gate insulation layer 150 may be formed on the first insulating interlayer 140a to cover the second active layer ACT2. The second gate electrode GE2 may be disposed on the third gate insulation layer 150 to substantially overlap the second channel region CN2 of the second active layer ACT2 in the thickness direction.

The second insulating interlayer 140b may be formed on the third gate insulating layer 150 to cover the second gate electrode GE2.

The first contact electrode CNT1 and the second contact electrode CNT2 may penetrate, e.g., extend through, the second insulating interlayer 140b, the third gate insulation layer 150, the first insulating interlayer 140a, the second gate insulation layer 130, and the first gate insulation layer 120, and may be in contact with the intermediate conductive layer ICL formed on the first contact region CR1 and the second contact region CR2, respectively.

As described with reference to FIGS. 1 and 2, the first contact electrode CNT1 and the second contact electrode CNT2 may be formed of a single-layered metal pillar (e.g., a single-layered copper pillar).

The first connection wiring CE1 and the second connection wiring CE2 may be formed on the second insulating interlayer 140b to be in contact with or be connected to the first contact electrode CNT1 and the second contact electrode CNT2, respectively. As described above, the first wiring CE1 and the second wiring CE2 may have a multi-layered structure, and may have a sequentially stacked structure of the first metal layer ML1, the second metal layer ML2, and the third metal layer ML3.

As described above, the light-emitting element ED may be electrically connected to the first transistor element TR1 through the second connection wiring CE2.

The third contact electrode CNT3 and the fourth contact electrode CNT4 may penetrate, e.g., extend through, the second insulating interlayer 140b and the third gate insulation layer 150 to be connected to or in contact with the third contact region CR3 and the fourth contact region CR4 of the second active layer ACT2, respectively.

Portions of the third contact electrode CNT3 and the fourth contact electrode CNT4 may be disposed on the second insulating interlayer 140b to substantially serve as a connection wiring. According to embodiments, the third contact electrode CNT3 and the fourth contact electrode CNT4 may have a multi-layered structure.

In some embodiments, the third contact electrode CNT3 and the fourth contact electrode CNT4 may have a multi-layered structure substantially the same as or similar to that of the first and second connection wirings CE1 and CE2. In an embodiment, the third contact electrode CNT3 and the fourth contact electrode CNT4 may each have a sequential stacked structure of the first metal layer ML1, the second metal layer ML2, and the third metal layer ML3.

According to the above-described embodiments, a contact connection structure included in the first transistor element TR1 having a relatively high aspect ratio may be formed in a stacked structure of the contact electrode CNT1 and CNT2, and the connection wiring CE1 and CE2, thereby suppressing defects such as disconnection and void of the contact connection structure. The contact electrodes CNT3 and CNT4 included in the second transistor element TR2 having a relatively low aspect ratio may be formed to include a connection wiring portion.

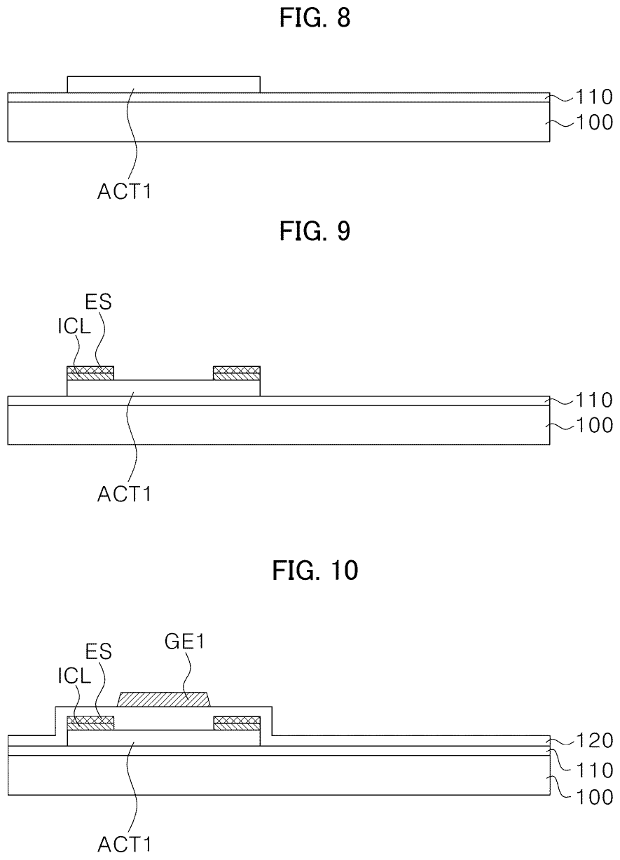

FIGS. 8 to 20 are schematic cross-sectional views illustrating a method of manufacturing a display panel or a display device according to embodiments. For example, FIGS. 8 to 20 illustrate a method of manufacturing the display panel or the display device described with reference to FIG. 7. Detailed descriptions on materials described with reference to FIGS. 1, 2 and 7 are omitted.

Referring to FIG. 8, the barrier layer 110 may be formed on the base substrate 100, and the first active layer ACT1 may be formed on the barrier layer 110.

The barrier layer 110 may be formed by a deposition process such as a chemical vapor deposition (CVD) process, a sputtering process, an atomic layer deposition (ALD) process, etc., to include the above-mentioned inorganic insulating material.

For example, an amorphous silicon layer may be formed on a top surface of the barrier layer 110, and then heat-treated to form the silicon layer. The silicon layer may be patterned by a photo-lithography process to form the first active layer ACT1. In an embodiment, the first active layer ACT1 may be formed as a low-temperature polysilicon (LTPS) layer.

Referring to FIG. 9, the intermediate conductive layer ICL and an etch-stop layer ES may be formed on both end portions or both side portions of the first active layer ACT1.

According to embodiments, a metal layer and a transparent metal oxide layer covering the first active layer ACT1 may be sequentially formed on the barrier layer 110 by a deposition process such as a sputtering process. The metal layer may be formed to include a metal having high stability and adhesion such as titanium, and the transparent oxide layer may be formed to include a transparent conductive oxide or an oxide semiconductor.

The transparent metal oxide layer and the metal layer may be partially etched by a photo-lithography process to form the intermediate conductive layer ICL and an etch-stop layer ES sequentially on each of both side portions or both end portions of the first active layer ACT1.

Referring to FIG. 10, the first gate insulation layer 120 covering the first active layer ACT1, the etch-stop layer ES and the intermediate conductive layer ICL may be formed on the barrier layer 110. The first gate insulation layer 120 may be formed by a deposition process such as a CVD process to include the above-mentioned inorganic insulating material.

The first gate electrode GE1 overlapping a portion of the first active layer ACT1 may be formed on the first gate insulation layer 120. A first conductive layer including the above-described metal may be formed by a deposition process such as a sputtering process. The first conductive layer may be patterned by a photo-lithography process to form the first gate electrode GE1.

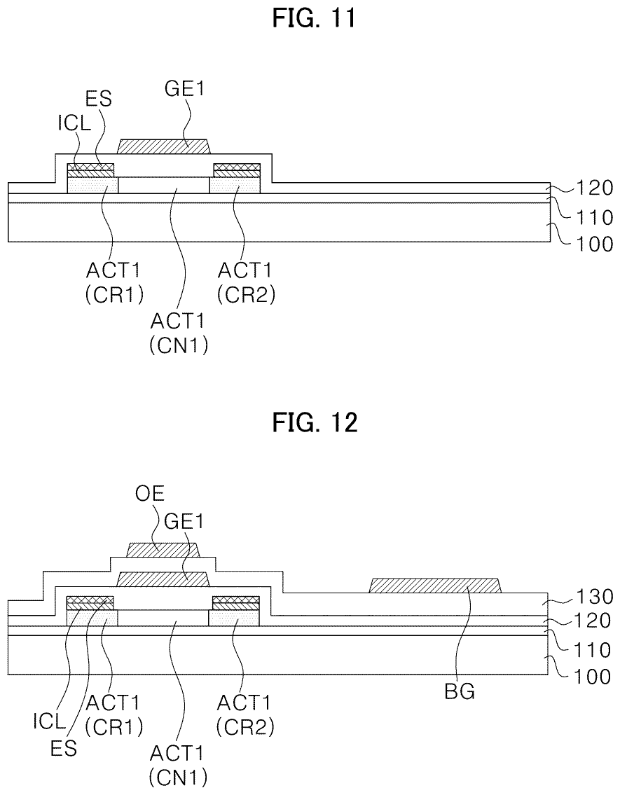

Referring to FIG. 11, the first contact region CR1 and the second contact region CR2 may be formed in the first active layer ACT1.

According to embodiments, an impurity doping process using the first gate electrode GE1 as an ion implantation mask may be performed. In an embodiment, p-type impurities may be doped on the both side portions of the first active layer ACT1 by the ion implantation process or the impurity doping process.

Thus, conductivity of the both side portions of the first active layer ACT1 may be increased to form the first contact region CR1 and the second contact region CR2. A portion of the first active layer ACT1 between the first contact region CR1 and the second contact region CR2 which may substantially overlap the first gate electrode GE1 may be defined as the first channel region CN1.

According to embodiments, each of the etch-stop layer ES and the intermediate conductive layer ICL may have a sufficiently small thickness so that impurities or injected ions may pass through the etch-stop layer ES and the intermediate conductive layer ICL. In some embodiments, each thickness of the etch-stop layer ES and the intermediate conductive layer ICL may be in a range from about 50 Å to about 200 Å, or from about 50 Å to about 150 Å.

Referring to FIG. 12, the second gate insulation layer 130 covering the first gate electrode GE1 may be formed on the first gate insulation layer 120. The second gate insulation layer 130 may be formed by a deposition process such as a CVD process to include the above-mentioned inorganic insulating material.

A second conductive layer including the above-described metal may be formed on the second gate insulation layer 130 by a deposition process such as a sputtering process. The second conductive layer may be patterned by a photo-lithography process to form the overlapping electrode OE that may overlap the first gate electrode GE1 in the thickness direction.

According to embodiments, the rear metal layer BG may be formed together from the second conductive layer by the photo-lithography process.

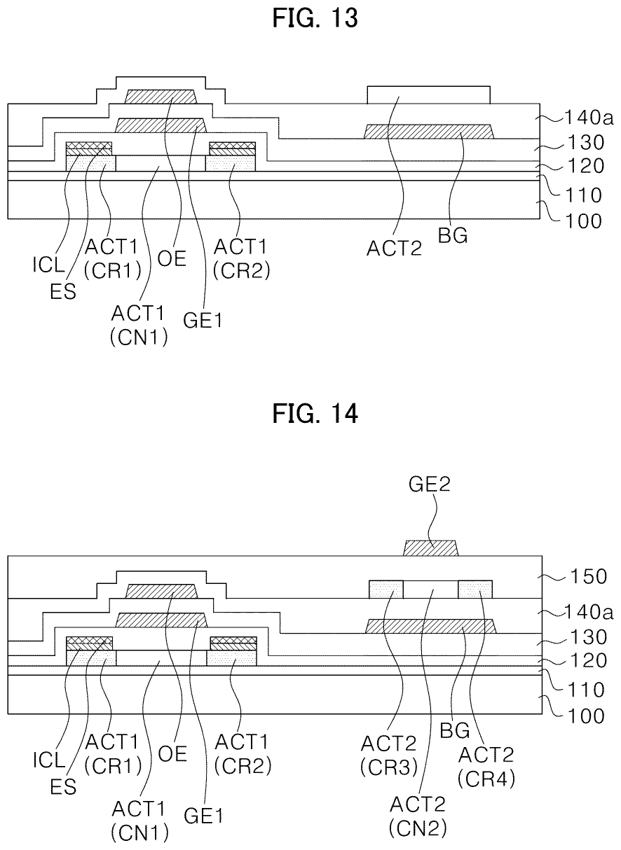

Referring to FIG. 13, the first insulating interlayer 140a covering the overlapping electrode OE and the rear metal layer BG may be formed on the second gate insulation layer 130. The first insulating interlayer 140a may be formed by a deposition process such as a CVD process to include the above-mentioned inorganic insulating material.

The second active layer ACT2 overlapping the rear metal layer BG may be formed on the first insulating interlayer 140a. According to embodiments, an oxide semiconductor layer including the above-mentioned oxide semiconductor may be formed on the first insulating interlayer 140a by a deposition process such as a sputtering process. The oxide semiconductor layer may be patterned through a photo-lithography process to form the second active layer ACT2 overlapping the rear metal layer BG.

Referring to FIG. 14, the third gate insulation layer 150 covering the second active layer ACT2 may be formed on the first insulating interlayer 140a. The third gate insulation layer 150 may be formed by a deposition process such as a CVD process to include the above-mentioned inorganic insulation material.

A third conductive layer including the above-described metal may be formed on the third gate insulation layer 150 by a deposition process such as a sputtering process. The third conductive layer may be patterned by a photo-lithography process to form the second gate electrode GE2 overlapping a portion of the second active layer ACT2.

In some embodiments, the third contact region CR3 and the fourth contact region CR4 may be formed at one side portion and the other side portion of the second active layer ACT2, respectively, by an impurity implantation process or an ion doping processes using the second gate electrode GE2 as an ion implantation mask. A portion of the second active layer ACT2 between the third contact region CR3 and the fourth contact region CR4 substantially overlapping the second gate electrode GE2 may be defined as the second channel region CN2.

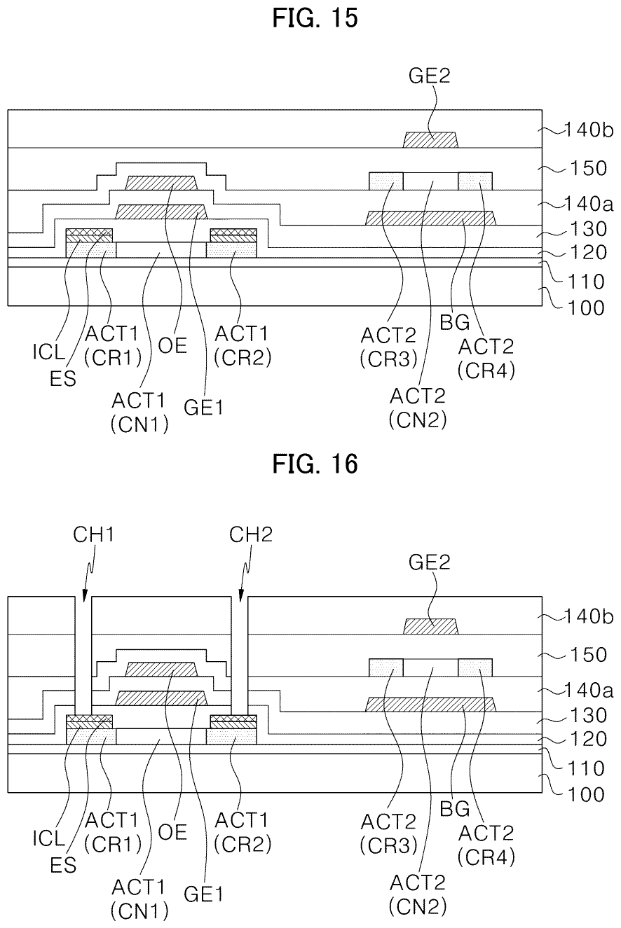

Referring to FIG. 15, the second insulating interlayer 140b covering the second gate electrode GE2 may be formed on the third gate insulation layer 150. The second insulating interlayer 140b may be formed by a deposition process such as a CVD process to include the above-mentioned inorganic insulating material.

Referring to FIG. 16, a first contact hole CH1 and a second contact hole CH2 may be formed to expose the etch-stop layer ES on the first contact region CR1 and the second contact region CR2, respectively.

According to embodiments, the second insulating interlayer 140b, the third gate insulation layer 150, the first insulating interlayer 140a, the second gate insulation layer 130, and the first gate insulation layer 120 may be sequentially etched by a first etching process.

The first etching process may include an anisotropic etching process. According to embodiments, the first etching process may include a dry etching process using an etching gas. The dry etching may be blocked by the etch-stop layer ES including the transparent metal oxide having an etching resistance with respect to the dry etching process. Thus, a top surface of the etch-stop layer ES may be exposed by the first contact hole CH1 and the second contact hole CH2.

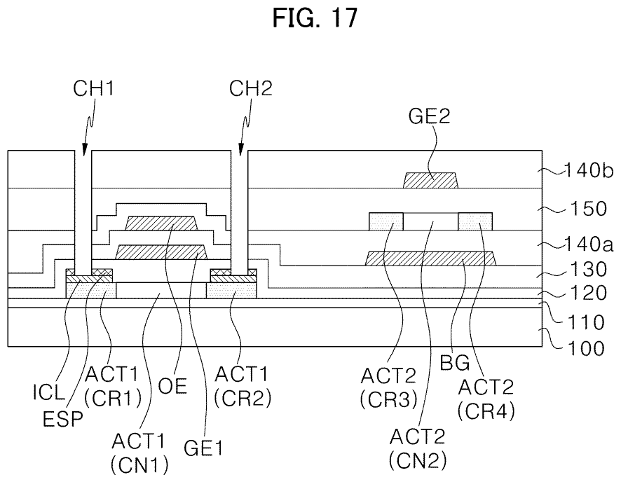

Referring to FIG. 17, the first contact hole CH1 and the second contact hole CH2 may be additionally extended by a second etching process.

According to embodiments, a wet etching process may be performed to additionally remove a portion of the etch-stop layer ES exposed through the first contact hole CH1 and the second contact hole CH2. For example, a portion of the etch-stop layer ES overlapping the first contact hole CH1 and the second contact hole CH2 may be removed by injecting an etchant having an etch selectivity for the transparent metal oxide through the first contact hole CH1 and the second contact hole CH2.

Accordingly, the first contact hole CH1 and the second contact hole CH2 may be additionally extended to partially expose a top surface of the intermediate conductive layer ICL. The etch-stop pattern ESP formed by etching the etch-stop layer ES may remain on a peripheral portion of the intermediate conductive layer ICL where the top surface of the intermediate conductive layer ICL is not exposed.

In some embodiments, as described with reference to FIG. 5, an under-cut portion may be formed in the etch-stop pattern ESP by using an isotropic etching property of the wet etching process.

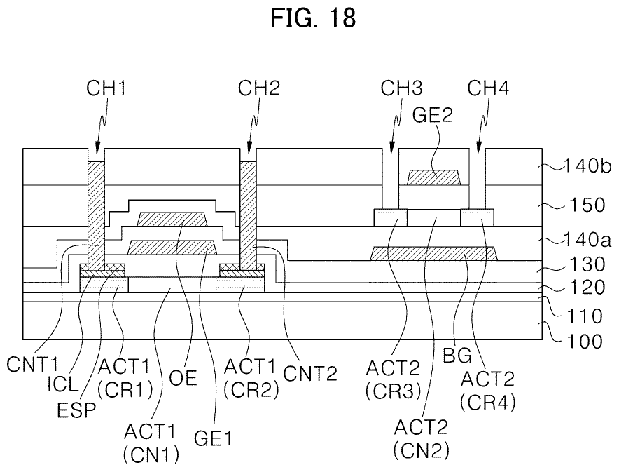

Referring to FIG. 18, the first contact electrode CNT1 and the second contact electrode CNT2 may be formed by a plating process in which the intermediate conductive layer ICL exposed by the first contact hole CH1 and the second contact hole CH2 may be used as a plating seed layer or a plating initiation layer. The plating process may include a copper plating process. In this case, the first contact electrode CNT1 and the second contact electrode CNT2 may have a Cu-pillar shape.

The intermediate conductive layer ICL may function as a protective layer for preventing damages to the contact regions CR1 and CR2 in the contact hole etching process as described above. Additionally, the intermediate conductive layer ICL may provide an adhesive force of copper in the copper plating process and may function as a blocking layer for preventing diffusion of copper.

In some embodiments, the plating process may be performed to partially fill the first contact hole CH1 and the second contact hole CH2. Accordingly, after the first contact electrode CNT1 and the second contact electrode CNT2 are formed, the first contact hole CH1 and the second contact hole CH2 may include residual portions.

Thereafter, the second insulating interlayer 140b and the third gate insulation layer 150 may be sequentially etched by a photo-lithography process to form a third contact hole CH3 and a fourth contact hole CH4 exposing top surfaces of the third contact region CR3 and the fourth contact region CR4, respectively. In the formation of the third contact hole CH3 and the fourth contact hole CH4, the first contact hole CH1 and the second contact hole CH2 may be shielded by a mask.

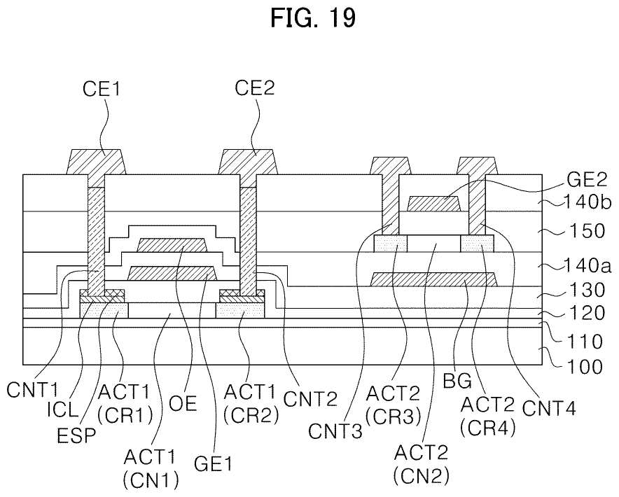

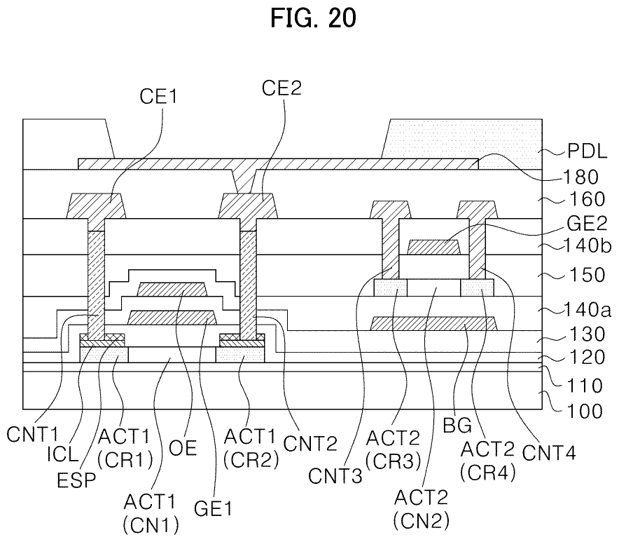

Referring to FIG. 19, the residual portions of the first contact hole CH1 and the second contact hole CH2, and the third contact hole CH3 and the fourth contact hole CH4 may be filled with a metal layer by a deposition process such as a sputtering process.

Although not illustrated in detail in FIG. 19, the metal layer may be formed as a multi-layered structure. According to embodiments, as described with reference to FIGS. 1 and 2, the first metal layer ML1, the second metal layer ML2, and the third metal layer ML3 may be sequentially formed on a top surface of the second insulating interlayer 140b to sufficiently fill the residual portions of the first contact hole CH1 and the second contact hole CH2, and the third contact hole CH4 and the fourth contact hole CH4.

Thereafter, the third metal layer ML3, the second metal layer ML2 and the first metal layer ML1 may be partially etched so that the first connection wiring CE1 and the second connection wiring CE2 filling the residual portions of the first contact hole CH1 and the second contact hole CH2 to be connected to or in contact with the first contact electrode CNT1 and the second contact electrode CNT2, respectively, may be formed.

In the etching process, the third contact electrode CNT3 and the fourth contact electrode CNT4 filling the third contact hole CH3 and the fourth contact region CR4 and being connected to the third contact region CR3 and the fourth contact region CR4, respectively, may be formed. The third contact electrode CNT3 and the fourth contact electrode CNT4 may be formed by the same etching process as that for the first connection wiring CE1 and the second connection wiring CE2.

The third contact electrode CNT3 and the fourth contact electrode CNT4 may be formed to include a connection electrode or a wiring portion formed on the top surface of the second insulating interlayer 140b.

According to embodiments of the present inventive concepts as described above, the second active layer ACT2 of the second transistor element may be located at an upper level than that of the first active layer ACT1 of the first transistor element with respect to the top surface of the base substrate 100. Thus, the third and fourth contact holes CH3 and CH4 for forming the contact electrode may have an aspect ratio smaller than that of the first and second contact holes CH1 and CH2.

The contact electrode and the connection wiring may be formed in the first and second contact holes CH1 and CH2 having a high aspect ratio by combining a plating process and a deposition process using the intermediate conductive layer ICL and the etch-stop layer ES. Accordingly, defects such as deterioration of step coverage properties and void generation that may occur in a contact hole having a high aspect ratio may be prevented.

In some embodiments, the contact electrode and the connection wiring may be substantially integrally formed in the third and fourth contact holes CH3 and CH4 having a low aspect ratio by a deposition process. The third and fourth contact holes CH3 and CH4 may have a relatively reduced height, so that the contact electrodes CNT3 and CNT4 may be formed while avoiding the deposition defects described with reference to FIG. 6.

Thereafter, the light-emitting element connected to the first transistor element may be formed.

Referring to FIG. 20, the planarization layer 160 may be formed on the second insulating interlayer 140b. The planarization layer 160 may be formed by a coating process, e.g., a spin coating process, to include the above-mentioned organic insulating material.

The planarization layer 160 may be partially etched to form, e.g., a via hole exposing a top surface of the second connection wiring CE2. The first electrode 180 filling the via hole may be formed on the planarization layer 160. For example, an electrode layer including the above-mentioned conductive material may be formed on the planarization layer 160 to sufficiently fill the via hole. The first electrode 180 may be formed by partially etching the electrode layer.

The pixel defining layer PDL may be formed on the planarization layer 160. The pixel defining layer PDL may cover a peripheral portion of the first electrode 180. In an embodiment, the pixel defining layer PDL may be formed by exposure and development processes after coating a photosensitive organic material such as a polysiloxane resin, a polyimide resin, an acrylic resin, or the like. In an embodiment, the pixel defining layer PDL may be formed through a printing process such as an inkjet printing process using a polymer material or an inorganic material.

Referring again to FIGS. 1 and 2, the light-emitting portion EL may be formed on a top surface of the first electrode 180 and a sidewall of the pixel defining layer PDL exposed by the pixel defining layer PDL.

The light-emitting portion EL may be formed by a thermal deposition, a vaporization deposition, a vacuum deposition, a spin coating, an inkjet printing, a laser printing, a casting, a laser thermal transfer, or the like, to include the organic light-emitting material described above.

As described with reference to FIG. 3, the light-emitting portion EL may include the hole transport layer HTL, the emission layer EML, and the electron transport layer ETL.

In some embodiments, the hole transport layer HTL and the electron transport layer ETL may be continuously and commonly formed over a plurality of pixels or the first electrodes 180, and the pixel defining layer PDL. In some embodiments, the emission layer EML may be selectively patterned for each first electrode 180 of an individual pixel.

The second electrode 190 provided as a common electrode may be formed on the pixel defining layer PDL and the light-emitting portion EL, and then the encapsulation layer TFE protecting the pixels and the second electrode 190 may be formed. The encapsulation layer TFE may be formed to include a multi-layered structure of an inorganic insulating layer and an organic insulating layer. For example, the encapsulation layer TFE may be formed in a sequential stacked structure of a first inorganic insulating layer, an organic insulating layer and a second inorganic insulating layer.

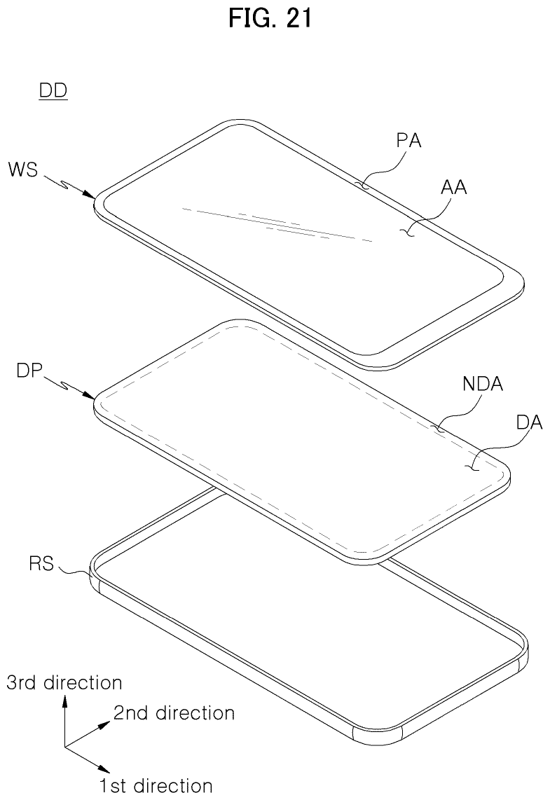

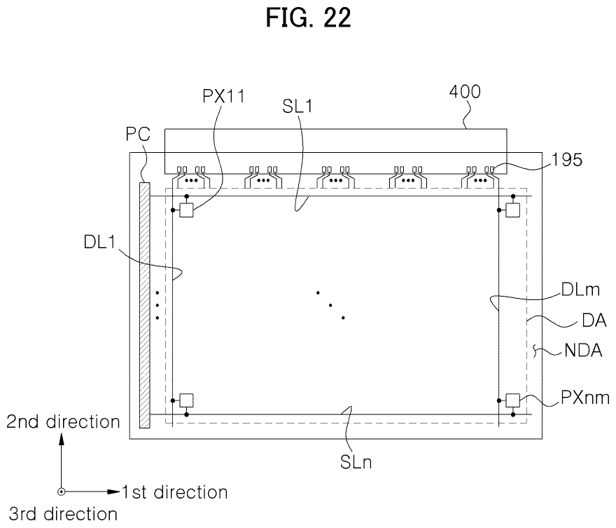

FIG. 21 is an exploded perspective view of a display device DD according to embodiments. FIG. 22 is a schematic plan view illustrating an arrangement of pixels of a display device according to embodiments.

In FIGS. 21 and 22, a first direction and a second direction may refer to two directions parallel to a window structure WS and/or a display surface of a display panel DP and perpendicular to each other. For example, the first direction may correspond to an X-direction (a row direction) of the display panel DP, and the second direction may correspond to a Y-direction (a column direction) of the display panel DP.

A third direction may be perpendicular to the first direction and the second direction. The third direction may correspond to a Z-direction (a thickness direction) of the display panel DP.

Referring to FIG. 21, the display device DD may include the window structure WS, the display panel DP and a rear structure RS. The rear structure RS, the display panel DP and the window structure WS may be sequentially stacked along the third direction.

The window structure WS may provide an external display surface recognized by a user of a display, and may include a transparent material film. For example, the window structure WS may include glass (e.g., ultra-thin glass (UTG)), a hard coating film, a plastic film, or the like.

An outer surface of the window structure WS may include an active area AA and a peripheral area PA. The active area AA may provide a surface from which an image of the display device DD is substantially displayed and to which a user's touch/command is input. The peripheral area PA may substantially correspond to a bezel area of the display device.

The display device DD and the display panel DP may have a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

For example, a sensor structure for a touch sensing or a fingerprint sensing may be disposed in the display panel DP or between the window structure WS and the display panel DP.

The rear structure RS may serve as a frame structure or a housing of the display device DD. A cover panel may be disposed between the rear structure RS and the display panel DP. The rear structure RS or the cover panel may include a plate (e.g., an SUS plate) that supports the display panel DP, a printed circuit board 400 (see FIG. 22), or the like. The rear structure RS or the cover panel may include an elastic body for absorbing shock of the display device DD.

Referring to FIG. 22, a plurality of pixels PX11 to PXnm may be arranged in the display area DA of the display panel DP.

In example embodiments, a pixel circuit including scan lines SL1 to SLn (or gate lines) forming first to n^{th} rows and data lines DL1 to DLm forming first to m^{th} columns may be arranged on the base substrate 100 of the display device DD or the display panel DP. Each of the pixels PX11 to PXnm may be connected to a corresponding n^{th} row scan line among a plurality of scan lines SL1 to SLn and a corresponding m^{th} column data line among a plurality of data lines DL1 to DLm.

For example, the scan lines SL1 to SLn may be connected to the gate electrode included in the thin film transistor. The data lines DL1 to DLm may be connected to, e.g., the connection wiring (e.g., the first connection wiring CE1) serving as the source electrode.

Each of the pixels PX11 to PXnm may further include a pixel circuit including a transistor as described below and the light-emitting element. Although not illustrated in detail in FIG. 22, the pixel circuit may further include wirings such as a power line, a ground line, etc.

FIG. 22 illustrates that the data lines DL1 to DLm extend in the second direction and the scan lines SL1 to SLn extend in the first direction, but the construction of the data lines and the gate lines is not limited to that illustrated in FIG. 22.

A peripheral circuit PC may be disposed in the peripheral area PA of the display device DD or the non-display area NDA of the display panel DP. For example, the peripheral circuit PC may include a gate driving circuit. The gate driving circuit may be integrated into the display panel DP by an oxide semiconductor gate (OSG) driver circuit process, an amorphous silicon gate (OSG) driver circuit process, or a polysilicon gate (PSG) driver circuit process.

The display device DD may further include the printed circuit board 400. Pads 195 of the pixel circuit (e.g., the data lines) may be assembled at one end portion of the non-display area NDA. The printed circuit board 400 may be electrically connected to the pixel circuit through the pads 195. For example, the printed circuit board 400 may be electrically connected to the pads 195 by a heating-compression process using a conductive intermediate structure such as an anisotropic conductive film (ACF).

An integrated circuit (IC) such as a data driving circuit may be disposed on the printed circuit board 400. In some embodiments, the integrated circuit (IC) chip in the form of a chip-on-film (COF) may be mounted on the printed circuit board 400.

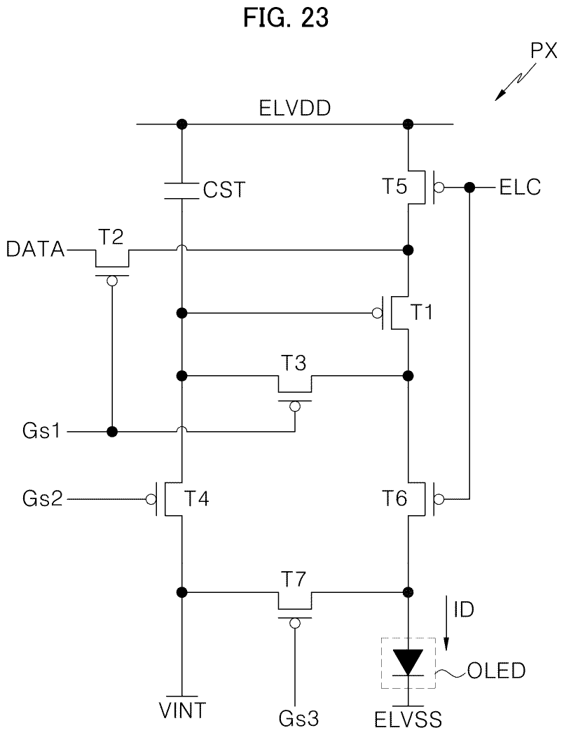

FIG. 23 is a pixel equivalent circuit diagram of a display device according to embodiments.

Referring to FIG. 23, each pixel PX may include a first transistor T1, a second transistor T2, a third transistor T3, a fourth transistor T4, a fifth transistor T5, a sixth transistor T6, a seventh transistor T7, and a storage capacitor CST.

The first transistor T1 may include a gate terminal, a first terminal and a second terminal. The gate terminal may be connected to the storage capacitor CST. The first terminal may be connected to the second transistor T2. The second terminal may be connected to the sixth transistor T6. The first transistor T1 may generate a driving current ID based on a voltage difference between the gate terminal and the first terminal. For example, the first transistor T1 may be referred to as a driving transistor.

The second transistor T2 may include a gate terminal, a first terminal and a second terminal. The gate terminal of the second transistor T2 may receive a first gate signal Gs1. The second transistor T2 may be turned on or turned off in response to the first gate signal Gs1. The first terminal of the second transistor T2 may receive a data voltage DATA. The second transistor T2 may provide the data voltage DATA to the first terminal of the first transistor T1 in response to the first gate signal Gs1. For example, the second transistor T2 may be referred to as a switching transistor.

The third transistor T3 may include a gate terminal, a first terminal and a second terminal. The gate terminal may receive the first gate signal Gs1. The first terminal may be connected to the gate terminal of the first transistor T1. The second terminal may be connected to the second terminal of the first transistor T1. The third transistor T3 may compensate for a threshold voltage of the first transistor T1. For example, the third transistor T3 may serve as a compensation transistor.

The fourth transistor T4 may include a gate terminal, a first terminal and a second terminal. The gate terminal may receive a second gate signal Gs2. The first terminal may be connected to the gate terminal of the first transistor T1. The second terminal may receive an initialization voltage VINT. The fourth transistor T4 may initialize the gate terminal of the first transistor T1.

The fifth transistor T5 may include a gate terminal, a first terminal and a second terminal. The gate terminal may receive an emission control signal ELC. The first terminal may receive a high-power supply voltage ELVDD. The second terminal may be connected to the first transistor T1.

The sixth transistor T6 may include a gate terminal, a first terminal and a second terminal. The gate terminal may receive the emission control signal ELC. The first terminal may be connected to the first transistor T1. The second terminal may be connected to an organic light emitting diode OLED. The sixth transistor T6 may transfer the driving current ID to the organic light emitting diode OLED in response to the emission control signal ELC.

The seventh transistor T7 may include a gate terminal, a first terminal and a second terminal. The gate terminal may receive a third gate signal Gs3. The first terminal may be connected to the organic light emitting diode OLED. The second terminal may receive the initialization voltage VINT. The seventh transistor T7 may initialize the organic light emitting diode OLED.

The storage capacitor CST may include a first terminal and a second terminal. The first terminal may receive the high-power supply voltage ELVDD. The second terminal may be connected to the gate terminal of the first transistor T1,

The organic light emitting diode OLED may include a first terminal and a second terminal. The first terminal may be connected to the sixth transistor T6. The second terminal may receive a low-power supply voltage ELVSS. The organic light emitting diode OLED may emit a light based on the driving current ID.

In some embodiments, the first transistor element TR1 including the above-described contact portion CP and the first active layer ACT1 that may include the silicon semiconductor may be used as the first transistor T1. In some embodiments, the second transistor element TR2 including the second active layer ACT2 that may include the oxide semiconductor may be used as the second transistor T2.

In FIG. 23, a structure of 7T1C including seven thin film transistors and one storage capacitor CST in each pixel PX is illustrated, but the pixel structure of the display device disclosed herein is not limited thereto.

For example, each pixel PX may include two or more transistors, and may have a structure such as 2T1C, 5T1C, 6T1C, 5T2C, 6T2C, or the like.

The above-described display device DD may include a liquid crystal display (LCD) device, an organic light-emitting diode (OLED) display device, a quantum dot light-emitting diode (QLED) display device, or the like. According to embodiments, the display device DD may be an OLED display device including an organic emission layer.

The display panel DP may include a thin film transistor array including the contact portion CP according to the above-described embodiments of the present disclosure.

For example, the display device DD may be implemented in the form of electronic devices such as a virtual reality (VR) or augmented reality display, a mobile phone (a smart phone), a tablet, a PC monitors, a digital camera, a camcorder, a portable game console, a vehicle display, a head-up display, a wearable display, a flexible display, a rollable display, a foldable display, or the like.

In some embodiments, the display device DD may be implemented in the form of a virtual reality glass (GVR).

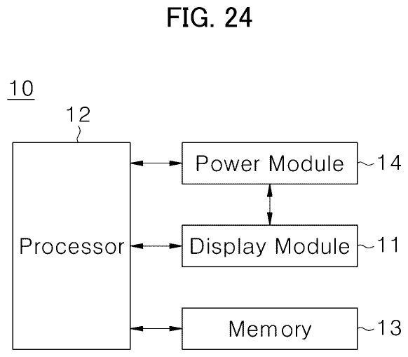

FIG. 24 is a block diagram of an electronic device 10 in accordance with an embodiment.

Referring to FIG. 24, the electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller. The processor 12 may include one or more processors.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power required for the operation of the electronic device 10.

At least one of components of the electronic device 10 as described above may be included in the display device according to the above-described embodiments. Additionally, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

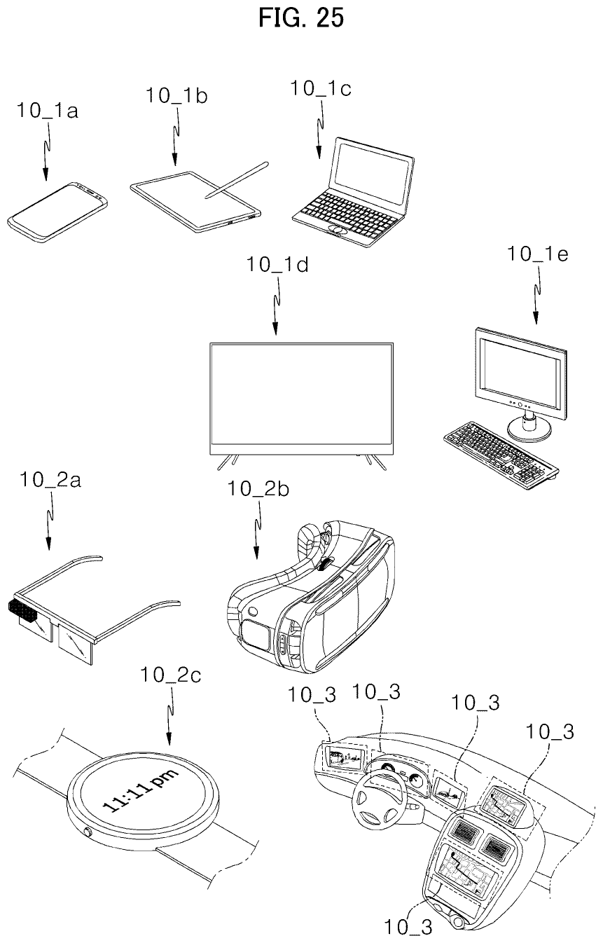

FIG. 25 is a schematic diagram of electronic devices in accordance with various embodiments.

Referring to FIG. 25, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, and the like; a wearable electronic device including a display module such as smart glasses 10_2a, a head mounted display 10_2b, a smart watch 10_2c, and the like; a vehicle electronic device 10_3 including a display module such as a center information display (CID) disposed at a vehicle instrument panel, a center fascia, a dashboard, etc., a head-up display, a room mirror display, and the like.

What is claimed is:

1. A display device, comprising:
a base substrate;
an active layer disposed on the base substrate, the active layer including a contact region and a channel region;
an intermediate conductive layer disposed on a top surface of the contact region of the active layer;
an etch-stop pattern disposed on a peripheral portion of a top surface of the intermediate conductive layer;
a gate electrode overlapping the channel region of the active layer;
a gate insulation layer disposed between the active layer and the gate electrode;
an insulating interlayer covering the gate electrode on the gate insulation layer;
a contact electrode extending through the insulating interlayer and the gate insulation layer to be disposed on the top surface of the intermediate conductive layer; and
a display element electrically connected to the contact electrode.

2. The display device of claim 1, wherein the intermediate conductive layer includes a metal layer, and the etch-stop pattern includes a transparent metal oxide.

3. The display device of claim 2, wherein the intermediate conductive layer includes titanium (Ti).

4. The display device of claim 1, wherein the etch-stop pattern surrounds a bottom portion of the contact electrode.

5. The display device of claim 1, wherein the etch-stop pattern includes an under-cut portion.

6. The display device of claim 5, wherein the contact electrode includes a vertical extension portion, and a horizontal extension portion having a width greater than a width of the vertical extension portion and contacting the under-cut portion of the etch-stop pattern.

7. The display device of claim 1, wherein the contact electrode has a single-layered metal pillar shape.

8. The display device of claim 1, further comprising a connection wiring disposed on the insulating interlayer to connect the display element and the contact electrode with each other, the connection wiring having a multi-layered structure.

9. The display device of claim 8, wherein the connection wiring comprises a first metal layer, a second metal layer and a third metal layer sequentially stacked from a top surface of the contact electrode.

10. The display device of claim 9, wherein the first metal layer and the third metal layer include a metal the same as a metal of the intermediate conductive layer, and the second metal layer includes a metal different from the metal of the intermediate conductive layer.

11. The display device of claim 10, wherein the first metal layer and the third metal layer include titanium (Ti), and the second metal layer includes aluminum (Al).

12. An electronic device, comprising:
the display device of claim 1;
a memory; and
one or more processors executing data included in the memory to control an operation of the display device.

13. The electronic device of claim 12, wherein the electronic device includes a virtual reality or augmented reality display, a mobile phone, a tablet, a PC monitor, a digital camera, a camcorder, a portable game console, a vehicle display, a head-up display, a wearable display, a flexible display, a rollable display, or a foldable display.

14. A display device, comprising:
a base substrate;
an active layer disposed on the base substrate, the active layer including a contact region and a channel region;
a gate electrode overlapping the channel region of the active layer;
a gate insulation layer disposed between the active layer and the gate electrode;
an insulating interlayer covering the gate electrode on the gate insulation layer;
a contact hole extending through the insulating interlayer and the gate insulation layer and overlapping the contact region;
a contact electrode partially filling the contact hole on the contact region;
a connection wiring filling a remaining portion of the contact hole to be connected to the contact electrode, the connection wiring having a multi-layered structure; and
a display element electrically connected to the connection wiring.

15. The display device of claim 14, further comprising
an intermediate conductive layer disposed between the contact electrode and the contact region; and
an etch-stop pattern disposed on a peripheral portion of a top surface of the intermediate conductive layer to surround a bottom portion of the contact electrode.

16. The display device of claim 15, wherein the intermediate conductive layer includes a metal layer, and the contact electrode has a single-layered pillar shape including a metal different from a metal of the intermediate conductive layer.

17. The display device of claim 15, wherein the etch-stop pattern includes a transparent metal oxide.

18. The display device of claim 14, wherein the connecting wiring includes a first metal layer, a second metal layer and a third metal layer sequentially stacked from a top surface of the contact electrode.

19. A method of manufacturing a display device, comprising:
forming an active layer on a base substrate;
sequentially forming an intermediate conductive layer and an etch-stop layer on a side portion of the active layer;
forming a gate insulation layer covering the active layer, the intermediate conductive layer and the etch-stop layer;
forming a gate electrode overlapping the active layer on the gate insulation layer;
forming an insulating interlayer covering the gate electrode on the gate insulation layer;
etching the insulating interlayer and the gate insulating layer by a first etching process to form a contact hole exposing a top surface of the etch-stop layer;
partially removing the etch-stop layer by a second etching process to extend the contact hole so that a top surface of the intermediate conductive layer is exposed;
forming a contact electrode filling the contact hole by a plating process from the top surface of the intermediate conductive layer exposed by the contact hole; and
forming a light-emitting element electrically connected to the contact electrode.

20. The method of manufacturing a display device according to claim 19, wherein the first etching process includes a dry etching and the second etching process includes a wet etching.
